(19) United States
(12) Patent Application Publication
(10) Pub. No.: US 2026/0134905 A1
(43) Pub. Date: May 14, 2026

(54) SEMICONDUCTOR DEVICE HAVING INPUT BUFFER CIRCUIT

(71) Applicant: MICRON TECHNOLOGY, INC., Boise, ID (US)

(72) Inventor: Shun Nishimura, Sagamihara (JP)

(73) Assignee: MICRON TECHNOLOGY, INC., Boise, ID (US)

(21) Appl. No.: 19/333,081

(22) Filed: Sep. 18, 2025

Related U.S. Application Data
(60) Provisional application No. 63/719,048, filed on Nov. 11, 2024.

(51) Int. Cl. G11C 11/4093

(52) U.S. Cl. CPC G11C 11/4093

(57) ABSTRACT

An example apparatus includes: a first input circuit coupled between a common source line and a first circuit node, the first input circuit being configured to be controlled by a first signal; a second input circuit coupled between the common source line and a second circuit node, the second input circuit being configured to be controlled by a second signal; an amplifier circuit configured to amplify a potential difference between the first and second circuit nodes; and an auxiliary current path configured to flow current from the common source line to the first and second circuit nodes regardless of the first and second signals.

### CROSS-REFERENCE TO RELATED APPLICATIONS

This application claims the filing benefit of U.S. Provisional Application No. 63/719,048, filed Nov. 11, 2024. This application is incorporated by reference herein in its entirety and for all purposes.

### BACKGROUND

There is a case where an input buffer of differential input type that compares the level of an input signal and the level of a reference potential is used for a semiconductor device such as a DRAM. In such an input buffer of differential input type, characteristics of a transistor constituting a circuit on an input side and characteristics of another transistor constituting a circuit on a reference side are required to match each other.

### BRIEF DESCRIPTION OF THE DRAWINGS

FIG. 1 is a block diagram showing a configuration of a semiconductor memory device according to an embodiment of the present disclosure;

FIG. 2 is a block diagram showing a configuration of main components of a data control circuit; and

FIGS. 3A-3C are circuit diagrams of a data latch circuit.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

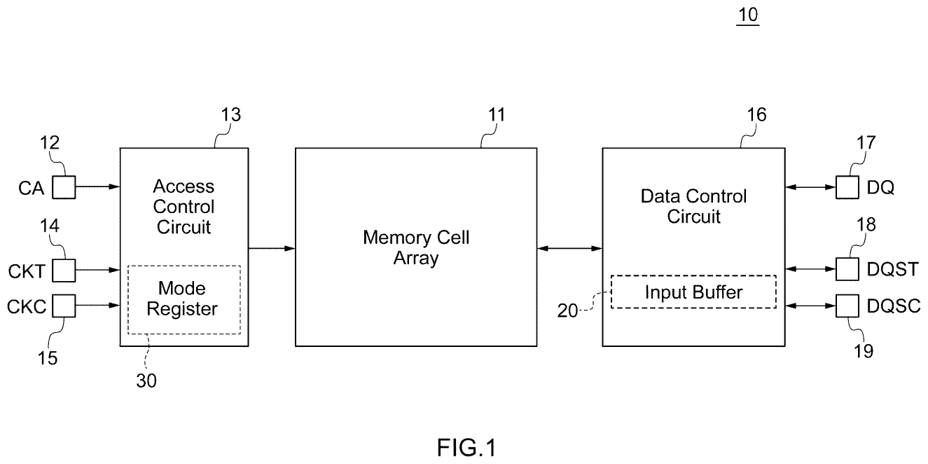

FIG. 1 is a block diagram showing a configuration of a semiconductor memory device 10 according to an embodiment of the present disclosure. The semiconductor memory device 10 shown in FIG. 1 is an LPDDR5 DRAM and includes a memory cell array 11. When access is made to the memory cell array 11, a command address signal CA is input to a command address terminal 12 from outside. The command address signal CA is supplied to an access control circuit 13. The access control circuit 13 synchronizes with complementary clock signals CKT and CKC respectively input to clock terminals 14 and 15, thereby decoding the command address signal CA, counting latencies, and the like.

When a command included in the command address signal CA indicates a read operation, the access control circuit 13 makes read-access to a memory cell included in the memory cell array 11 based on an address included in the command address signal CA. Read data DQ read from the accessed memory cell is output to outside from a data I/O terminal 17 via a data control circuit 16. When the command included in the command address signal CA indicates a write operation, write data DQ input to the data I/O terminal 17 is transferred to the memory cell array 11 via an input buffer circuit 20 included in the data control circuit 16. The write data DQ is input to the memory cell array 11 as it synchronizes with complementary data strobe signals DQST and DQSC respectively supplied to data strobe terminals 18 and 19. The write data DQ having been transferred to the memory cell array 11 is written in the memory cell included in the memory cell array 11 based on the address included in the command address signal CA.

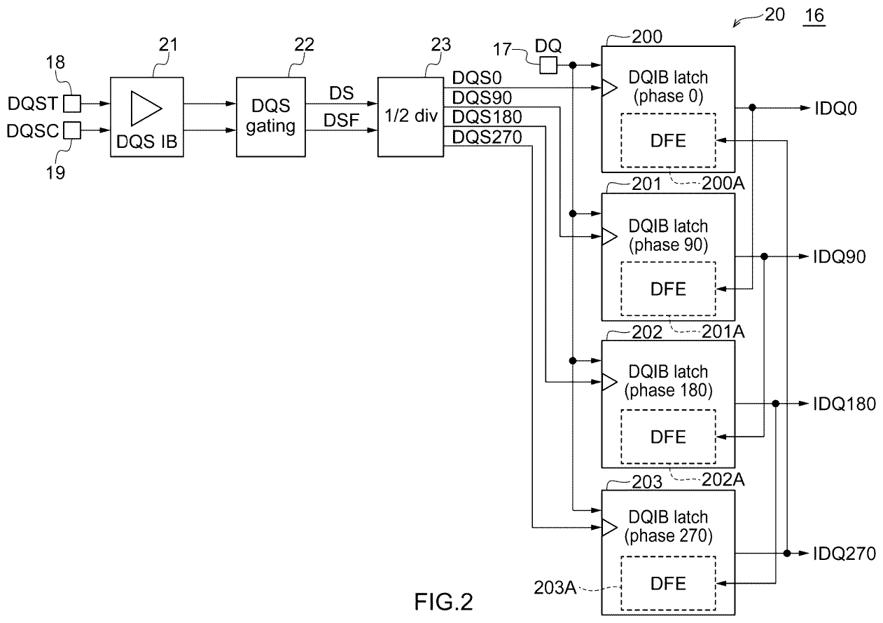

FIG. 2 is a block diagram showing a configuration of main components of the data control circuit 16. As shown in FIG. 2, the data control circuit 16 includes a gating circuit 22 that receives data strobe signals DQST and DQSC via an input buffer 21. Internal data strobe signals DS and DSF output from the gating circuit 22 respectively correspond to the data strobe signals DQST and DQSC. The internal data strobe signals DS and DSF are input to a dividing circuit 23. The dividing circuit 23 generates four-phase internal data strobe signals DQS0, DQS90, DQS180, and DQS270 by dividing the internal data strobe signals DS and DSF. When the phase of the internal data strobe signal DQS0 is 0°, the phases of the internal data strobe signals DQS90, DQS180, and DQS270 are 90°, 180°, and 270°, respectively. The internal data strobe signals DQS0, DQS90, DQS180, and DQS270 are supplied to the input buffer 20.

The input buffer 20 includes a data latch circuit 200 that synchronizes with the internal data strobe signal DQS0 to latch the write data DQ, a data latch circuit 201 that synchronizes with the internal data strobe signal DQS90 to latch the write data DQ, a data latch circuit 202 that synchronizes with the internal data strobe signal DQS180 to latch the write data DQ, and a data latch circuit 203 that synchronizes with the internal data strobe signal DQS270 to latch the write data DQ. Write data IDQ0, write data IDQ90, write data IDQ180, and write data IDQ270 respectively latched on the data latch circuits 200 to 203 are transferred to the memory cell array 11.

The data latch circuits 200, 201, 202, and 203 respectively include a DFE (Decision Feedback Equalizer) circuit 200A, a DFE circuit 201A, a DFE circuit 202A, and a DFE circuit 203A each of which reduces ISI (Intersymbol Interference) noise. Data latched on the data latch circuit 200 is fed back to the DFE circuit 201A included in the data latch circuit 201. Data latched on the data latch circuit 201 is fed back to the DFE circuit 202A included in the data latch circuit 202. Data latched on the data latch circuit 202 is fed back to the DFE circuit 203A included in the data latch circuit 203. Data latched on the data latch circuit 203 is fed back to the DFE circuit 200A included in the data latch circuit 200.

In this manner, four data latch circuits 200 to 203 are allocated to one data I/O terminal 17. While only one data I/O terminal 17 is shown in FIGS. 1 and 2, a plurality (eight, for example) of data I/O terminals 17 are provided in practice, and four data latch circuits 200 to 203 are allocated to each of the data I/O terminals 17.

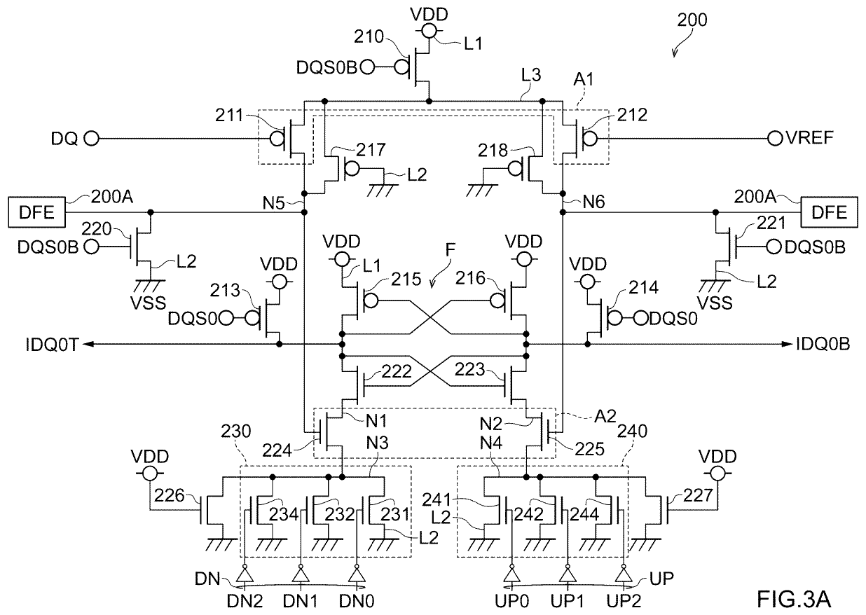

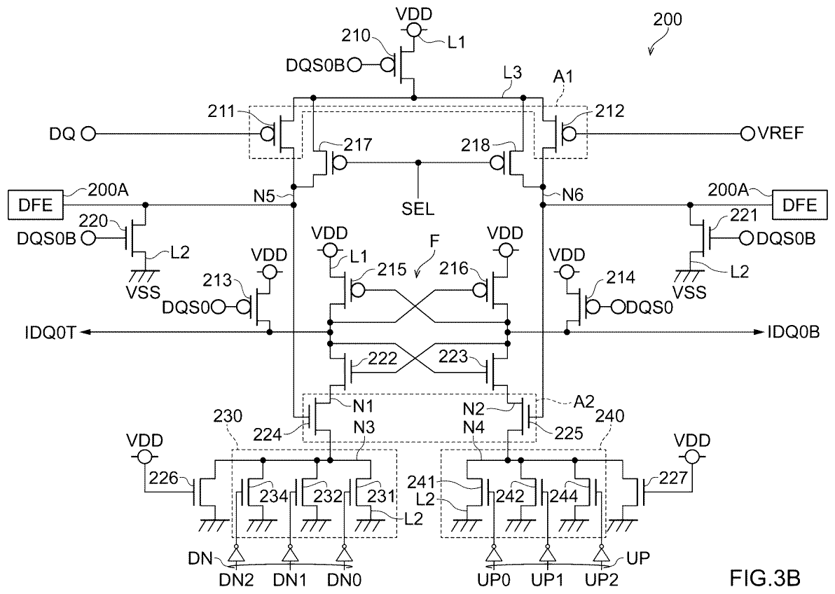

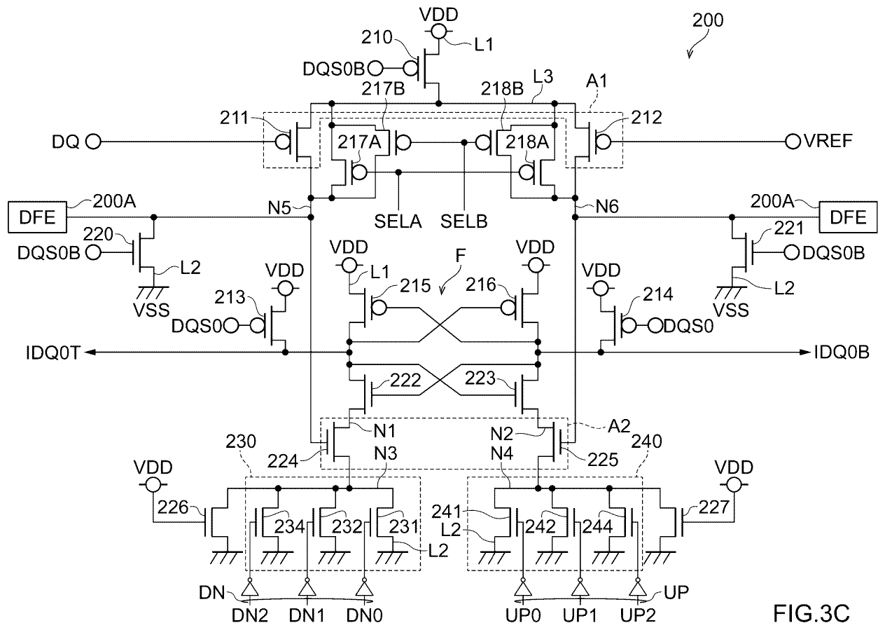

FIG. 3A is a circuit diagram of the data latch circuit 200 according to the first example. As shown in FIG. 3A, the data latch circuit 200 includes P-channel MOS transistors 210 to 218, N-channel MOS transistors 220 to 227, and current control circuits 230 and 240. The transistor 210 is coupled between a power line L1 supplied with a power potential VDD and a common source line L3. An inversion signal DQS0B of the internal data strobe signal DQS0 is input to a gate electrode of the transistor 210. The transistor 211 is coupled between the common source line L3 and a circuit node N5. The write data DQ is input from outside to a gate electrode of the transistor 211 via the data I/O terminal 17. The transistor 212 is coupled between the common source line L3 and a circuit node N6. A reference potential VREF is supplied to a gate electrode of the transistor 212. The transistors 211 and 212 constitute a differential amplifier circuit A1 that controls the amount of current flowing into the circuit nodes N5 and N6 based on a potential difference between the reference potential VREF and the write data DQ. The differential amplifier circuit A1 is activated when the inversion signal DQS0B of the internal data strobe signal DQS0 becomes a low level. The transistor 220 is coupled between the circuit node N5 and a power line L2 supplied with a ground potential VSS. A transistor 221 is coupled between the circuit node N6 and the power line L2 supplied with the ground potential VSS. The inversion signal DQS0B of the internal data strobe signal DQS0 is input to gate electrodes of the transistors 220 and 221. With this configuration, when the inversion signal DQS0B of the internal data strobe signal DQS0 becomes a high level, the circuit nodes N5 and N6 are precharged on the ground potential VSS and an amplifier circuit A1 is inactivated. Further, the DFE circuit 200A is coupled to each of the circuit nodes N5 and N6. In some examples, the transistors 211 and 212 may be referred to as input transistors 211 and 212.

The transistors 215, 216, 222, and 223 constitute a flip-flop circuit F. That is, the transistors 215 and 222 are coupled in series between the power line L1 supplied with the power potential VDD and a circuit node N1, and gate electrodes thereof are coupled in common to drains of the transistors 216 and 223. The circuit node N1 constitutes one input node of the flip-flop circuit F. The transistors 216 and 223 are coupled in series between the power line L1 supplied with the power potential VDD and a circuit node N2, and gate electrodes thereof are coupled in common to drains of the transistors 215 and 222. The circuit node N2 constitutes the other input node of the flip-flop circuit F. Internal write data IDQ0T is output from the drains of the transistors 215 and 222 constituting one output node. Internal write data IDQ0B is output from the drains of the transistors 216 and 223 constituting the other output node. When the internal data strobe signal DQS0 becomes a low level, internal write data IDQ0T/B is precharged on the power potential VDD by the transistors 213 and 214.

The transistor 224 is coupled between the circuit node N1 and a circuit node N3. A gate electrode of the transistor 224 is coupled to the circuit node N5. The circuit node N3 is coupled to the power line L2 supplied with the ground potential VSS via the current control circuit 230 and a transistor 226. A transistor 225 is coupled between the circuit node N2 and a circuit node N4. A gate electrode of the transistor 225 is coupled to the circuit node N6. The circuit node N4 is coupled to the power line L2 supplied with the ground potential VSS via the current control circuit 240 and the transistor 227. With this configuration, the transistors 224 and 225 constitute an amplifier circuit A2 that supplies an operating current to the flip-flop circuit F based on the potentials of the circuit nodes N5 and N6.

The current control circuit 230 is formed of transistors 231, 232, and 234 that are coupled in parallel between the circuit node N3 and the power line L2 supplied with the ground potential VSS. Inversion signals of each of bits DN0, DN1, and DN2 constituting a down-code signal DN are respectively input to gate electrodes of the transistors 231, 232, and 234. The down-code signal DN is a signal in binary form. The bit DN0 is a least significant bit of the down-code signal DN and the transistor 231 input with an inversion signal of the bit DN0 constitutes a least significant transistor. The bit DN2 is a most significant bit of the down-code signal DN and the transistor 234 input with an inversion signal of the bit DN2 constitutes a most significant transistor. Here, when the transistor size of the transistor 231 is set as “1”, the transistor size of the transistor 232 is “2” and the transistor size of the transistor 234 is “4”. Further, the transistor 226 is coupled in parallel to the current control circuit 230. Since the power potential VDD is applied to a gate electrode of the transistor 226 in a fixed manner, the transistor 226 is turned ON regardless of the down-code signal DN.

The current control circuit 240 is formed of transistors 241, 242, and 244 that are coupled in parallel between the circuit node N4 and the power line L2 supplied with the ground potential VSS. Inversion signals of each of bits UP0, UP1, and UP2 constituting an up-code signal UP are respectively input to gate electrodes of the transistors 241, 242, and 244. The up-code signal UP is a signal in binary form. The bit UP0 is a least significant bit of the up-code signal UP and the transistor 241 input with an inversion signal of the bit UP0 constitutes a least significant transistor. The bit UP2 is a most significant bit of the up-code signal UP and the transistor 244 input with an inversion signal of the bit UP2 constitutes a most significant transistor. Here, when the transistor size of the transistor 241 is set as “1”, the transistor size of the transistor 242 is “2” and the transistor size of the transistor 244 is “4”. Further, the transistor 227 is coupled in parallel to the current control circuit 240. Since the power potential VDD is applied to a gate electrode of the transistor 227 in a fixed manner, the transistor 227 is turned ON regardless of the up-code signal UP.

Here, the sizes of the transistor 231 and the transistor 241 are mutually the same. The sizes of the transistor 232 and the transistor 242 are mutually the same. The sizes of the transistor 234 and the transistor 244 are mutually the same. The sizes of the transistor 226 and the transistor 227 are mutually the same.

With such a circuit configuration, the amount of current flowing into the current control circuit 230 according to the down-code signal DN can be adjusted. Similarly, the amount of current flowing into the current control circuit 240 can be adjusted according to the up-code signal UP. Accordingly, when there is an input offset in the data latch circuit 200, by adjusting the amount of current flowing into the current control circuits 230 and 240 using the down-code signal DN and the up-code signal UP, the input offset can be cancelled.

The data latch circuit 200 shown in FIG. 3A further includes transistors 217 and 218. The transistor 217 is connected between the common source line L3 and the circuit node N5. That is, the transistor 217 is connected in parallel to the transistor 211. The transistor 218 is connected between the common source line L3 and the circuit node N6. That is, the transistor 218 is connected in parallel to the transistor 212. The gate electrode of each of the transistors 217 and 218 is connected to the power line L2. That is, the gate electrode of each of the transistors 217 and 218 is fixed to the ground potential VSS. Therefore, the transistors 217 and 218 are always in the ON state. Here, the size of the transistors 217 and 218 is sufficiently smaller than the size of the transistors 211 and 212. Instead of the transistors 217 and 218, a high-resistance resistor element may be used. In some examples, the transistors 217 and 218 may be referred to as auxiliary transistors 217 and 218.

As explained, the data latch circuit 200 includes auxiliary transistors 217 and 218 connected in parallel to the input transistors 211 and 212, respectively. Thus, when the inverted signal DQS0B of the internal data strobe signal DQS0 is activated to a low level to turn ON the transistor 210, a small current flows from the common source line L3 to the circuit nodes N5 and N6 via the transistors 217 and 218. As a result, since the levels of the circuit nodes N5 and N6 immediately rise after the inverted signal DQS0B of the internal data strobe signal DQS0 is activated to a low level, it is possible to make the amplifier circuit A2 and the flip-flop circuit F respond quickly after the write data DQ appears, even if the level of the power supply potential VDD is set relatively low.

FIG. 3B is a circuit diagram of a data latch circuit 200 according to the second example. The data latch circuit 200 shown in FIG. 3B is different from the data latch circuit 200 shown in FIG. 3A in that a selection signal SEL is supplied in common to the gate electrodes of the transistors 217 and 218. The level of the selection signal SEL is determined by a parameter set in the mode register 30 included in the access control circuit 13 shown in FIG. 1. For example, when the parameter set in the mode register 30 indicates that the level of the power supply potential VDD is less than a predetermined value, the level of the selection signal SEL is set to the ground potential VSS. When the parameter indicates that the level of the power supply potential VDD is equal to or greater than the predetermined value, the level of the selection signal SEL is set to the power supply potential VDD. As a result, when the level of the power supply potential VDD is less than the predetermined value, the transistors 217 and 218 are enabled, so that the same operation as the data latch circuit 200 shown in FIG. 3A can be performed. On the other hand, when the level of the power supply potential VDD is equal to or greater than the predetermined value, the transistors 217 and 218 are disabled, so that it is possible to prevent a decrease in the potential difference between the circuit nodes N5 and N6 caused by the transistors 217 and 218 being turned on. Alternatively, the level of the selection signal SEL may be changed in multiple stages according to the parameters set in the mode register 30. This makes it possible to finely adjust the amount of current flowing through the transistors 217 and 218.

FIG. 3C is a circuit diagram of a data latch circuit 200 according to the third example. The data latch circuit 200 shown in FIG. 3C differs from the data latch circuit 200 shown in FIG. 3A in that two transistors 217A and 217B are connected in parallel to the transistor 211, and two transistors 218A and 218B are connected in parallel to the transistor 212. The sizes of the transistors 217A, 217B, 218A, and 218B may be the same as each other, or the sizes of the transistors 217A and 218A may be larger than the sizes of the transistors 217B and 218B. At least, the sizes of the transistors 217A and 218A are the same as each other, and the sizes of the transistors 217B and 218B are the same as each other. A selection signal SELA is supplied in common to the gate electrodes of the transistors 217A and 218A, and a selection signal SELB is supplied in common to the gate electrodes of the transistors 217B and 218B. The levels of the selection signals SELA and SELB are determined by parameters set in the mode register 30 included in the access control circuit 13 shown in FIG. 1. This makes it possible to adjust the amount of current flowing through the transistors 217A, 217B, 218A, and 218B in multiple stages according to the level of the power supply potential VDD indicated by the parameters set in the mode register 30.

Each of other data latch circuits 201 to 203 constituting the input buffer 20 has a circuit configuration identical to that of the data latch circuit 200 shown in FIGS. 3A-3C. Mutually different down-code signals DN and up-code signals UP are used for each of the data latch circuits 200 to 203, and thus each input offset in the data latch circuits 200 to 203 is cancelled in each of these circuits.

Although this invention has been disclosed in the context of certain preferred embodiments and examples, it will be understood by those skilled in the art that the inventions extend beyond the specifically disclosed embodiments to other alternative embodiments and/or uses of the inventions and obvious modifications and equivalents thereof. In addition, other modifications which are within the scope of this invention will be readily apparent to those of skill in the art based on this disclosure. It is also contemplated that various combination or sub-combination of the specific features and aspects of the embodiments may be made and still fall within the scope of the inventions. It should be understood that various features and aspects of the disclosed embodiments can be combined with or substituted for one another in order to form varying mode of the disclosed invention. Thus, it is intended that the scope of at least some of the present invention herein disclosed should not be limited by the particular disclosed embodiments described above.

1. An apparatus comprising:
a differential amplifier circuit having a pair of first and second input transistors;
a first auxiliary transistor coupled in parallel to the first input transistor, and
a second auxiliary transistor coupled in parallel to the second input transistor,
wherein the first and second auxiliary transistors are configured to be fixed to an ON state.

2. The apparatus of claim 1, wherein each of the first and second auxiliary transistors is smaller in size than each of the first and second input transistors.

3. The apparatus of claim 1, wherein a control electrode of the first auxiliary transistor is short-circuited to a control electrode of the second auxiliary transistor.

4. The apparatus of claim 1,
wherein the first input transistor is configured to be controlled by an input data supplied from outside, and
wherein the second input transistor is configured to be controlled by a reference potential with respect to the input data.

5. The apparatus of claim 4, further comprising a common source transistor coupled between a first power line and a common source of the first and second input transistors,
wherein the common source transistor has a control electrode supplied with an internal data strobe signal.

6. The apparatus of claim 1, wherein each of the first and second auxiliary transistors has the same conductivity type as each of the first and second input transistors.

7. An apparatus comprising:
a first input circuit coupled between a common source line and a first circuit node, the first input circuit being configured to be controlled by a first signal;
a second input circuit coupled between the common source line and a second circuit node, the second input circuit being configured to be controlled by a second signal;
an amplifier circuit configured to amplify a potential difference between the first and second circuit nodes; and
an auxiliary current path configured to operatively flow current from the common source line to the first and second circuit nodes regardless of the first and second signals.

8. The apparatus of claim 7, wherein the auxiliary current path includes a first transistor coupled in parallel to the first input circuit and a second transistor coupled in parallel to the second input circuit.

9. The apparatus of claim 8,
wherein the first input circuit includes a third transistor coupled between the common source line and the first circuit node,
wherein the second input circuit includes a fourth transistor coupled between the common source line and the second circuit node, and
wherein each of the first and second transistors is smaller in size than each of the third and fourth transistors.

10. The apparatus of claim 8, wherein a control electrode of the first transistor is short-circuited to a control electrode of the second transistor.

11. The apparatus of claim 10, wherein the control electrode of each of the first and second transistor is fixed to an active level.

12. The apparatus of claim 10, further comprising a control circuit configured to control a level of the control electrodes of the first and second transistors.

13. The apparatus of claim 10,
wherein the control electrode of each of the first and second transistor is suppled with an active level when a first operation mode, and
wherein the control electrode of each of the first and second transistor is suppled with an inactive level when a second operation mode.

14. The apparatus of claim 10, wherein the auxiliary current path further includes a fifth transistor coupled in parallel to the first input circuit and a sixth transistor coupled in parallel to the second input circuit.

15. The apparatus of claim 14, further comprising a control circuit configured to control a level of the control electrodes of the first and second transistors and control a level of control electrodes of the fifth and sixth transistors.

16. The apparatus of claim 7, wherein the amplifier circuit includes:
a first transistor having a control electrode coupled to the first circuit node;
a second transistor having a control electrode coupled to the second circuit node; and
a flip-flop circuit configured to operate based on current flowing through the first and second transistors.

17. The apparatus of claim 16, further comprising a third transistor coupled between a power line and the common source line,
wherein the third transistor has a control electrode supplied with an internal data strobe signal.

18. The apparatus of claim 17, wherein the first signal is an input data supplied from outside.

19. The apparatus of claim 18, wherein the second signal is a reference potential with respect to the input data.

20. An apparatus comprising:
first and second power lines supplied with first and second power potentials different from each other,
a first transistor coupled between the first power line and a common source line;
a second transistor coupled between the common source line and a first circuit node;
a third transistor coupled between the common source line and a second circuit node;
a fourth transistor coupled between the first circuit node and the second power line;
a fifth transistor coupled between the second circuit node and the second power line;
an amplifier circuit configured to amplify a potential difference between the first and second circuit nodes;
a sixth transistor coupled in parallel to the first transistor, and
a seventh transistor coupled in parallel to the second transistor,
wherein each of the first, second, third, sixth, and seventh transistors has a first conductivity type,
wherein each of the fourth and fifth transistors has a second conductivity type opposite to the first conductivity type,
wherein each of the first, second, third, fourth, and fifth transistors has a control electrode supplied with an internal data strobe signal, and
wherein each of the sixth and seventh transistors has a control electrode short-circuited to the second power line.
